(19) United States
(12) Patent Application Publication
(10) Pub. No.: US 2019/0310859 A1
(43) Pub. Date: Oct. 10, 2019

(54) ACCELERATED STARTUP THROUGH PARALLEL DECOMPRESSION OF RAM DISKS

(71) Applicant: Visteon Global Technologies, Inc., Van Buren Township, MI (US)

(72) Inventors: Thomas Kopfstedt, Karlsruhe (DE); Kai Wang, Ettlingen (DE); Thorsten Wilmer, Bruchsal (DE)

(21) Appl. No.: 15/945,481

(22) Filed: Apr. 4, 2018

(51) Int. Cl. G06F 9/4401; G06F 3/06; H03M 7/30

(52) U.S. Cl. CPC G06F 9/4401; G06F 3/0604; G06F 3/0608; H03M 7/6005; G06F 3/068; H03M 7/6023; H03M 7/702; G06F 3/0661

(57) ABSTRACT

A system for an accelerated startup including a primary processing core of a computer, a plurality of secondary processing cores of the computer, connected to the primary processing core, and a non-volatile memory connected to the primary processing core and to the plurality of secondary processing cores. The system may include a non-volatile memory may include an initial program load and an initial RAM disk containing a compressed operating system kernel image, where the primary core decompresses the operating system kernel image upon execution of the initial program load. The system may include a plurality of compressed RAM disks, where the plurality of compressed RAM discs may be decompressed in parallel by the secondary processing cores. The system may include applications stored on the plurality of RAM discs that may be executed in parallel by the secondary processing cores after the decompression in parallel has been completed.

### BACKGROUND

A computer typically executes a number of tasks upon startup (i.e., turning on the computer). These tasks may include accessing memory, which may store a variety of applications (i.e., software), for the operation of the computer. The memory may be accessed by a direct memory access (DMA) module, and may include non-volatile memory and random access memory (RAM). Non-volatile memory is define herein as memory that maintains data stored within without a connection to a power source. RAM is defined herein as memory that does not maintain data stored within absent a connection to a power source (such as provided by the computer). As the startup process continues, applications may be retrieved from non-volatile memory and placed in RAM so that a processor core may access and execute the applications. Once all of the applications in RAM have been executed by the processor core, a system using some or all of the applications running on the computer may be available for use.

### SUMMARY

The present disclosure relates to a system for an accelerated startup including a primary processing core of a computer, a plurality of secondary processing cores of the computer, connected to the primary processing core, and a non-volatile memory connected to the primary processing core and to the plurality of secondary processing cores. The system may include a non-volatile memory may include an initial program load and an initial RAM disk containing a compressed operating system kernel image, where the primary core decompresses the operating system kernel image upon execution of the initial program load. The system may include a plurality of compressed RAM disks, where the plurality of compressed RAM discs may be decompressed in parallel by the secondary processing cores. The system may include applications stored on the plurality of RAM discs that may be executed in parallel by the secondary processing cores after the decompression in parallel has been completed.

The accelerated startup accelerated startup may also include after startup of the computer, the initial program load may be loaded from the non-volatile memory to the RAM of the computer.

The accelerated startup may also include the initial program loading the compressed kernel image and the initial RAM disk to the RAM of the computer.

The accelerated startup may also include a kernel image that may be decompressed by the primary processing core.

The accelerated startup may also include a kernel image that may be initialized by the primary processing core.

The accelerated startup accelerated startup may include a kernel image that may initialize the initial RAM disk and loads the initial RAM disk to the RAM of the computer.

The accelerated startup may also include a kernel that may load the plurality of compressed RAM disks from the non-volatile memory to the RAM of the computer.

The accelerated startup may also include a kernel that may use a first of the plurality of secondary processing cores to decompress a first of the plurality of compressed RAM disks and a second of the plurality of secondary processing cores to decompress a second of the plurality of compressed RAM disks.

The accelerated startup may also include a kernel that may use the first of the plurality of secondary processing cores executes at least one application stored on the first of the plurality of compressed RAM disks and may use the second of the plurality of secondary processing cores executes at least one application stored on the second of the plurality of compressed RAM disks simultaneously.

The accelerated startup may also include a first of the plurality of secondary processing cores and the second of the plurality of secondary processing cores, that may, after executing at least one application respectively, initiate partitioning of the RAM of the computer.

In embodiments, a method for an accelerated startup may include activating a computer having a primary core processor, initial program load (IPL), a direct memory access (DMA), and random access memory (RAM).

The method may further include enabling the RAM via the DMA of the primary core processor.

The method may further include loading, by the IPL, an initial RAM disk and a compressed operating system kernel to the RAM from a non-volatile memory.

The method may further include decompressing, by the primary core, the operating system kernel on the RAM.

The method may further include executing, by the primary core, the operating system kernel on the RAM.

The method may further include loading a plurality of compressed RAM disks from the non-volatile memory to the RAM of the computer while the operating system kernel is decompressed and executed.

The method may further include parallel decompressing, by a plurality of secondary core processors, the plurality of compressed RAM disks on the RAM of the computer.

The method may further include parallel executing, by the plurality of secondary core processors, applications stored on decompressed RAM disks on the RAM of the computer.

### BRIEF DESCRIPTION OF THE DRAWINGS

These and other features and advantages of the present invention will be readily appreciated, as the same becomes better understood by reference to the following detailed description when considered in connection with the accompanying drawings wherein:

FIG. 1 is a flow chart of an exemplary boot sequence illustrating an embodiment of the accelerated startup through parallel decompression of RAM disks, according to embodiments of the disclosure;

FIG. 2 is a block diagram of an exemplary accelerated startup through parallel decompression of RAM disks, according to embodiments of the disclosure;

FIG. 3 is a block diagram of an exemplary decompression of a RAM disk, according to embodiments of the disclosure;

FIG. 4 is a block diagram of an exemplary system that may utilize the accelerated startup through parallel decompression of RAM disks, according to embodiments of the disclosure; and

FIG. 5 is a block diagram of an exemplary decompression according to the accelerated startup through parallel decompression of a RAM disk with multiple stacks of applications, according to embodiments of the disclosure.

### DETAILED DESCRIPTION

During computer startup, decompression algorithms in many situations use only a single processing core, for example, on a system on a chip (SoC). Only later in the startup process are additional cores used; however by that time, a considerable amount of the startup period as elapsed. This situation could be considered a “bottleneck” in that in additional cores may be available, but only a single core is used for the initial startup of the computer, with other cores possibly utilized later in the startup process. A computer system operating in this manner may be slow or unresponsive during startup as a result of this bottleneck.

In many computer systems, an accelerated startup is desired and in some cases, necessary. For example, a vehicle advanced driver assistance system (ADAS) may be required to operational for the vehicle to function as a transportation device. Without ADAS loaded and operating on the vehicle computer, some or all of the vehicle's abilities may not be available. For example, a driver may activate (i.e., start, initiate), a vehicle equipped with ADAS (i.e., software and/or hardware integrated with the vehicle), and the driver may be unable to operate the vehicle until ADAS is fully loaded and operating on the vehicle computer. This situation is undesirable as the driver may need to be transported and may be unwilling or inconvenienced by waiting for ADAS to finish loading and launching on the vehicle computer. In another example, a vehicle may not be able to operate without ADAS fully loaded and operating on the vehicle computer, thus an accelerated startup of ADAS (for example) is desired.

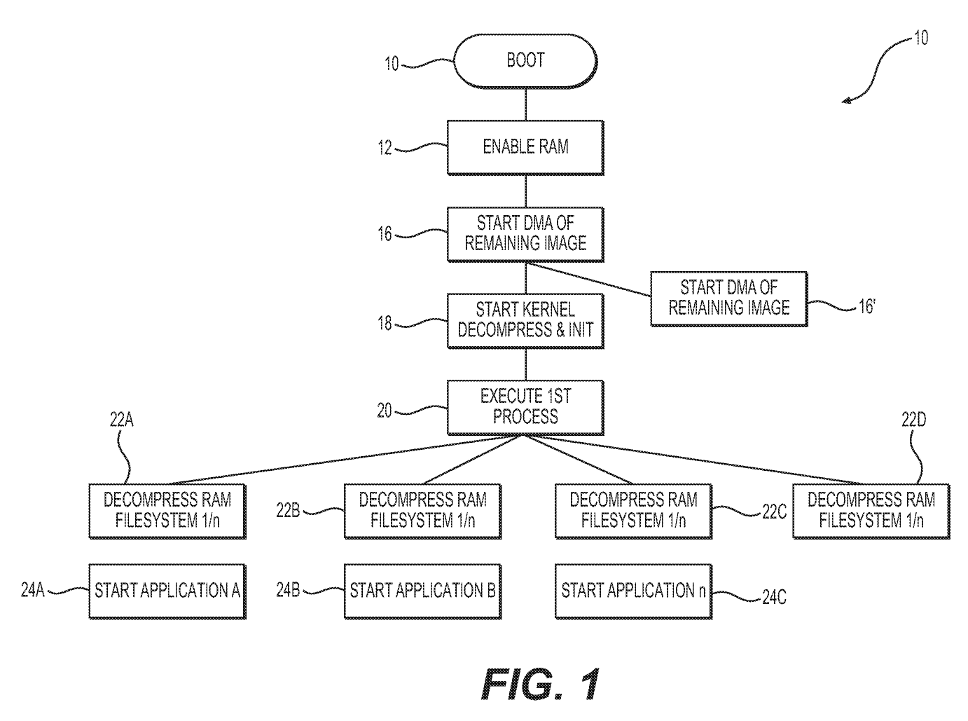

Referring to the Figures, like numerals indicate corresponding parts throughout the several views, a flowchart detailing the steps of an embodiment of the system and method 10 for the accelerated startup of a computer system through parallel decompression of RAM disks is shown in FIG. 1. System and method 10 includes a boot step 12, an enablement of RAM step 14, a direct memory access controller (DMA) that accesses the RAM in steps 16, 16′, kernel decompression and initialization in step 18, execution of a first process in step 20, decompression of at least one RAM File system in steps 22A-22D, and execution of at least one application in steps 24A-24C.

In an embodiment, a computer system, such as ADAS, is stored in non-volatile memory but is not able to executed from the non-volatile memory due to performance limitations (among other reasons) of the non-volatile memory. Rather, ADAS (or another computer system and/or application) should therefore be executed from RAM in order to bring ADAS (or another computer system and/or application) on-line quickly and otherwise operational.

In the first step of method 10, boot step 12, a computer storing ADAS in non-volatile memory, such as a vehicle, is activated (i.e., turned on). Alternatively, the computer is a stand-alone system and not part of a larger computer system (e.g., ADAS stored on non-volatile memory of a mobile device). Boot step 12 may include providing electrical power to the computer motherboard, direct memory access unit, and RAM, among other components. Boot step 12 may include control by a BIOS (basic input/output system) and/or other computer system checks for system errors. After boot step 12 is complete, the computer RAM is enabled in step 14. Boot step 12 may be of a hard (cold) boot type or a soft (warm) boot type. For example, a hard boot may include activation of a vehicle with ADAS from a completely powered-down state (off or power disconnected). A soft boot may include activation of a vehicle with ADAS that was partially shut down (i.e., an “accessory only” or stop-start situation).

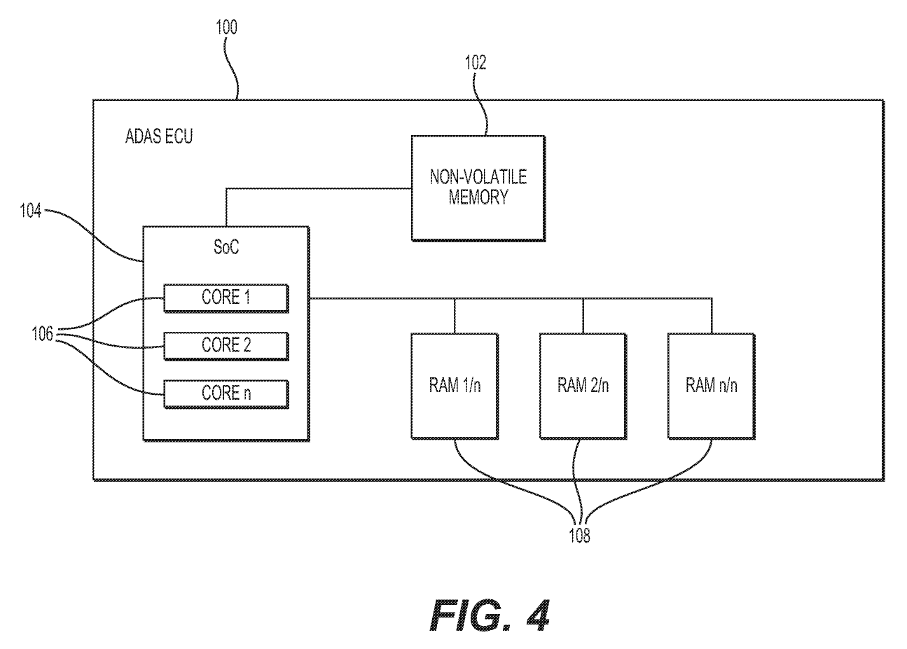

RAM enablement step 14 includes activating and accessing the RAM 108 to receive ADAS stored on the non-volatile memory 102 of the ADAS ECU 100. The RAM 108 is required to (decompress and later execute) ADAS with system on a chip (SoC) 104 including cores 106 of ADAS ECU 100 as shown in FIG. 4.

Step 16 includes activating the DMA controller of the SoC 104 to image non-volatile memory 102 to RAM 108. The imaging may include an operating system (OS), an operating system kernel, an initial program load (IPL), and one or more applications. For example, the OS may be Linux, the OS kernel may be a Linux kernel, and the applications may be ADAS applications, which may all be imaged from non-volatile memory 102 to RAM 108 in step 16. Step 16 may be repeated for multiple instances in step 16′.

In step 18, the OS kernel (in this embodiment), is decompressed in RAM 108 and initialized. The OS kernel may be executed on one or more cores 106 of SoC 104 in one embodiment. In another embodiment, the OS kernel may be executed on only one core of SoC 104. In yet another embodiment, different OS kernels may be executed in parallel on cores 106.

In step 20, a first process is executed. For example, the first process may include the command system of ADAS, which in turn includes programming to activate or execute additional applications of ADAS (e.g., sub-systems of ADAS—sensors, cameras, etc.). Upon execution of the first process, additional decompression of RAM 108 occurs in step 22.

In step 22A-22D, portions of RAM 108 are decompressed for execution of applications of ADAS. For example, in step 22A, a portion of RAM 108 is decompressed for the execution of an Application A of ADAS in step 24A. Similarly, in steps 22B-22C, respective portions of RAM 108 are decompressed for the execution of Applications B and C in steps 24B, 24C.

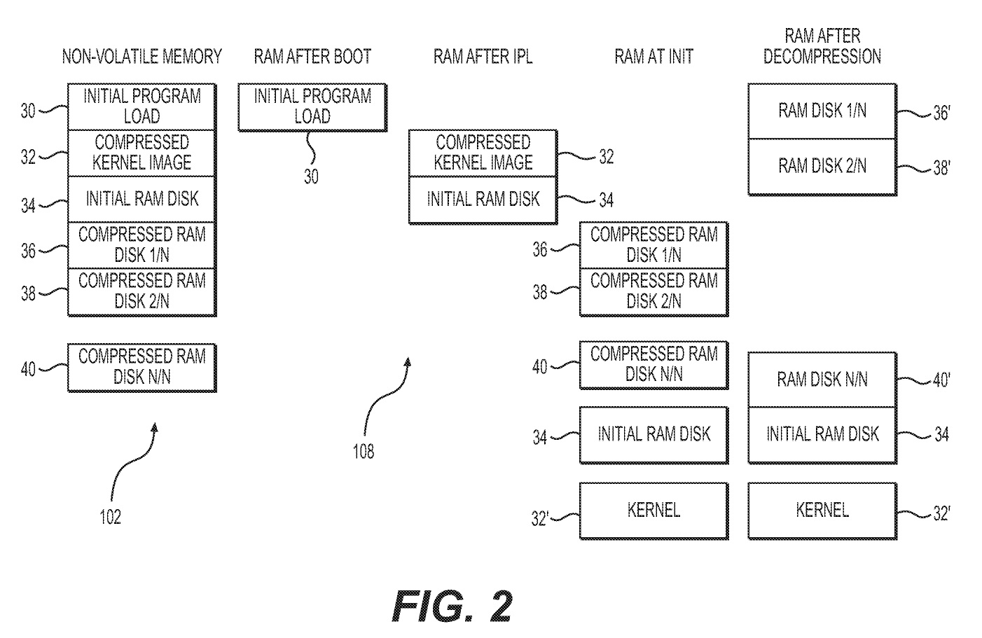

Referring now to FIG. 2, a block diagram illustrating the contents of the non-volatile memory 102 and RANI 108 is shown. Initially, such as when the vehicle is off (i.e., not operating), the power is disconnected, or the vehicle is powered-down (but not off), non-volatile memory 102 may include an initial program load (IPL) 30, a compressed kernel image 32, an initial RANI disk 34, a first compressed RANI disk 36, a second compressed RANI disk 38, and one or more additional compressed RAM disks 40.

Upon startup (i.e., boot), IPL 30 is loaded to RAM 108 and initialized. IPL 30 loads compressed kernel image 32 and initial RAM disk 34 to RAM 108. During loading by IPL 30, compressed kernel image 32 is initialized to kernel 50 and compressed RANI disks 34, 36, and 38 are loaded to RANI 108. Next compressed RANI disks 34, 36, 38 are decompressed in parallel to RANI 108 by one or more cores 106.

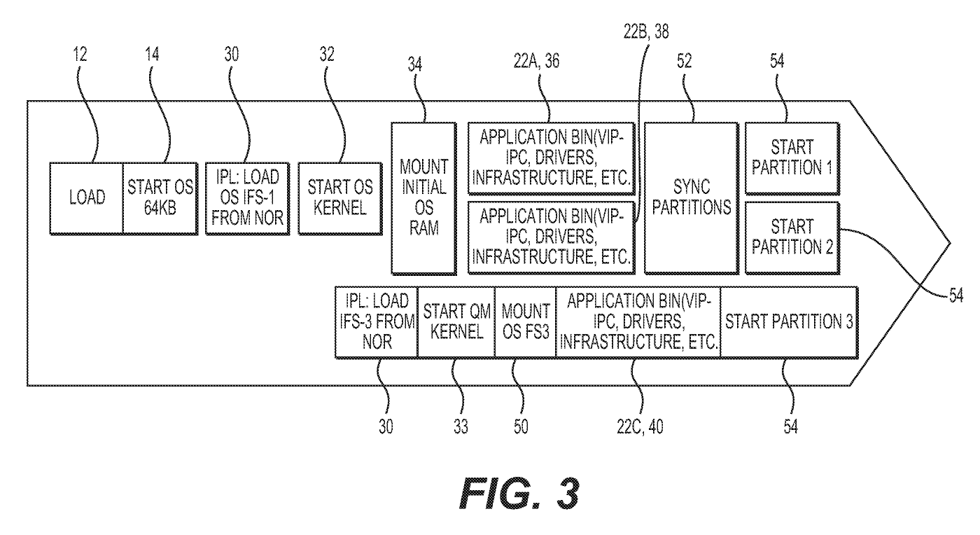

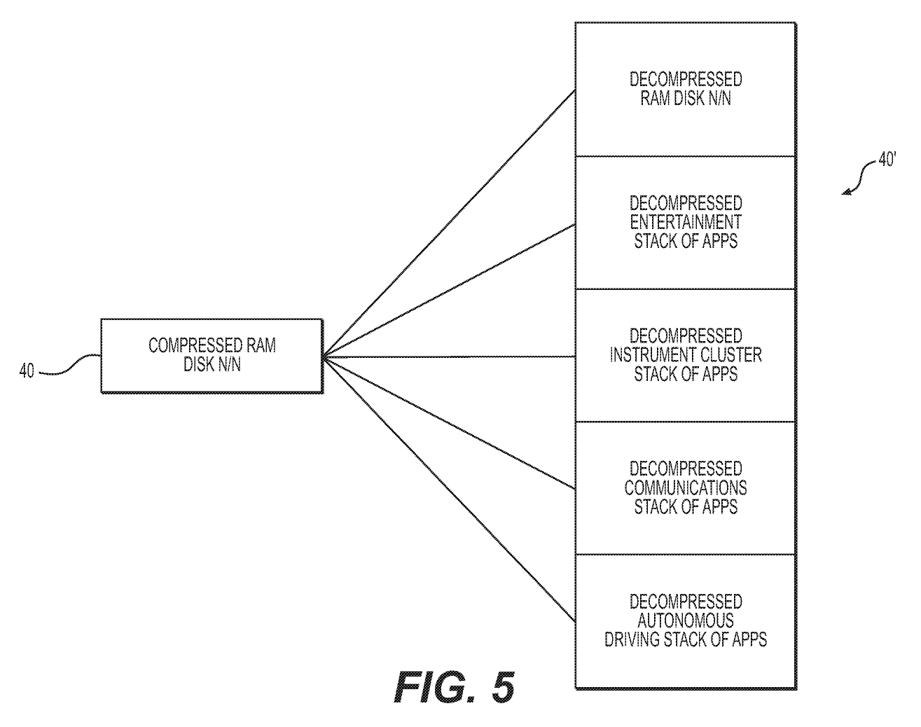

Referring now to FIG. 3, an embodiment of the present disclosure is provided. At a first step, shown in FIG. 1, startup/boot 12 occurs followed by the start of the OS 14. An initial program load (IPL) 30 follows, wherein the OS (e.g., IFS-1) is loaded from non-volatile memory 102 (as shown in FIG. 2). The next step (18 as shown in FIGS. 1 and 32 in FIG. 2, the OS kernel is initiated. At or approximately at the same time, IPL loads IFS-3 from non-volatile memory 102. The next step includes mounting (i.e., loading), the initial OS into RAM 108 and starting quality managed kernel 33. A next step 50 includes mounting OS FS3 followed by (or simultaneous with) the decompression of compressed RAM disks 22A-22D (as shown in FIG. 1) or 36, 38, 40 (as shown in FIG. 2) by cores 106. Compressed RAM disks 22A-22D, 36, 38, 40 may include multiple images that may contain multiple applications (i.e., application bin folder), that may contain vehicle interface processor-inter processor communication (VIP-IPC), one or more drivers, and other infrastructure applications. For example, the applications may include an entertainment stack, an instrumentation cluster stack, a communication stack, and/or an autonomous driving stack of applications (as shown in FIG. 5). A next step 52 involves synchronizing partitions within RAM 108 followed by step 52, wherein each partition of RAM 108 is initialized.

Using the disclosed accelerated startup, a shorter startup time of a computer system may be achieved. The computer system may be included within a larger computer system (e.g., ADAS within a vehicle) or the computer system may be self-contained (e.g., a mobile device). As disclosed above, utilizing more than a single processor core on a system-on-a-chip (SoC) 104, the startup process can be divided (completed in parallel) between the multiple cores 106 (such as the multiple cores 106 of the ADAS ECU 100) to occur simultaneously or nearly simultaneously, rather than in a linear process, whereby each application is decompressed and initiated from non-volatile memory 102 to RAM 108 in turn, while other applications are left compressed on non-volatile memory 102 and waiting for decompression and initiation.

The accelerated startup through parallel (or divided) decompression of RAM disks 34, 36, 38 stored in non-volatile memory 102 may be achieved by multiple processor cores 106 of SoC 104. In the example of ADAS ECU 100, the parallel decompression may enable applications of ADAS to initiate and/or execute more rapidly, allowing a vehicle equipped with ADAS to become operational (i.e., able to be driven or operate) more quickly.

In an embodiment, ADAS may be stored on non-volatile memory 102 but due to the limitations of non-volatile memory 102, execution of ADAS should occur on RAM 108. In other words, on-demand loading of ADAS from non-volatile memory is not feasible. Upon initiation of ADAS, such as by vehicle start or ADAS activation, to improve the startup time of ADAS, RAM 108 storing ADAS is divided (i.e., split), include multiple disks of RAM 108 while still compressed, allowing the multiple cores 106 of SoC 104 to decompress the multiple disks of RAM 108 in parallel.

Parallel (or divided) decompression is achieved by one or more decompression algorithms executed by a first core 106. After the accelerated startup process has initiated, additional cores 106 are used to decompress the multiple disks of RAM 108. At startup or boot, the first core 106 initiates the IPL 30 that enables RAM 108 of ADAS ECU 100, loads compressed kernel image 32 and initial RAM disk 34. Next the DMA unit of SoC 104 loads the remaining compressed RAM disks 36, 38, 40 of non-volatile memory 102 to RAM 108. An OS kernel 32 (e.g., Linux kernel), initiates afterwards, and since all of ADAS has been moved from non-volatile memory 102 to RAM 108, ADAS can operate on RAM 108 without needing to access non-volatile memory 102 and deal with its performance limitations as compared to RAM 108. In embodiments, OS kernel 32 and initial RAM disk 34 are designed to minimize their size (i.e., use the least amount of memory as possible), such that first core 106 may decompress, initiate and/or execute OS kernel 32 and initial RAM disk 34.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A system for an accelerated startup, comprising:
a primary processing core of a computer;
a plurality of secondary processing cores of the computer, connected to the primary processing core; and
non-volatile memory connected to the primary processing core and to the plurality of secondary processing cores, the non-volatile memory including:
an initial program load;
an initial RAM disk containing a compressed operating system kernel image, wherein the primary core decompresses the operating system kernel image upon execution of the initial program load; and
a plurality of compressed RAM disks, wherein the plurality of compressed RAM discs are decompressed in parallel by the secondary processing cores, and applications stored on the plurality of RAM discs are executed in parallel by the secondary processing cores after the decompression in parallel has been completed.

2. The accelerated startup of claim 1, wherein after startup of the computer, the initial program load is loaded from the non-volatile memory to the RAM of the computer.

3. The accelerated startup of claim 2, wherein the initial program load loads the compressed kernel image and the initial RANI disk to the RANI of the computer.

4. The accelerated startup accelerated startup of claim 3, wherein the kernel image is decompressed by the primary processing core.

5. The accelerated startup of claim 4, wherein the kernel image is initialized by the primary processing core.

6. The accelerated startup of claim 5, wherein the kernel image initializes the initial RANI disk and loads the initial RAM disk to the RAM of the computer.

7. The accelerated startup of claim 6, wherein the kernel loads the plurality of compressed RAM disks from the non-volatile memory to the RAM of the computer.

8. The accelerated startup of claim 7, wherein the kernel, using a first of the plurality of secondary processing cores to decompress a first of the plurality of compressed RAM disks and a second of the plurality of secondary processing cores to decompress a second of the plurality of compressed RAM disks.

9. The accelerated startup of claim 8, wherein the kernel, using the first of the plurality of secondary processing cores executes at least one application stored on the first of the plurality of compressed RAM disks and using the second of the plurality of secondary processing cores executes at least one application stored on the second of the plurality of compressed RAM disks simultaneously.

10. The accelerated startup of claim 9, wherein the first of the plurality of secondary processing cores and the second of the plurality of secondary processing cores, after executing at least one application respectively, initiate partitioning of the RAM of the computer.

11. A method for an accelerated startup, comprising:
activating a computer having a primary core processor, initial program load (IPL), a direct memory access (DMA), and random access memory (RAM);
enabling the RAM via the DMA of the primary core processor;
loading, by the IPL, an initial RAM disk and a compressed operating system kernel to the RAM from a non-volatile memory;
decompressing, by the primary core, the operating system kernel on the RAM;
executing, by the primary core, the operating system kernel on the RAM;
loading a plurality of compressed RAM disks from the non-volatile memory to the RAM of the computer while the operating system kernel is decompressed and executed;
parallel decompressing, by a plurality of secondary core processors, the plurality of compressed RAM disks on the RAM of the computer; and
parallel executing, by the plurality of secondary core processors, applications stored on decompressed RAM disks on the RAM of the computer.
